(19) United States
(12) Patent Application Publication
(10) Pub. No.: US 2023/0403916 A1
(43) Pub. Date: Dec. 14, 2023

(54) DISPLAY DEVICE

(71) Applicant: Japan Display Inc., Tokyo (JP)

(72) Inventor: Hideyuki TAKAHASHI, Tokyo (JP)

(73) Assignee: Japan Display Inc., Tokyo (JP)

(21) Appl. No.: 18/455,629

(22) Filed: Aug. 25, 2023

Related U.S. Application Data
(63) Continuation of application No. PCT/JP2021/048241, filed on Dec. 24, 2021.

(30) Foreign Application Priority Data
Feb. 26, 2021 (JP) 2021-030481

(51) Int. Cl. H10K 59/88; H10K 59/122

(52) U.S. Cl. CPC H10K 59/88; H10K 59/122

(57) ABSTRACT

According to one embodiment, a display device includes a base, a first insulating layer arranged on the base, a first electrode arranged on the first insulating layer overlapping with a pixel in a display area, a second insulating layer arranged on the first insulating layer and including an aperture overlapping with the first electrode, a first spacer partially arranged on the second insulating layer overlapping with the display area, a partition arranged on the second insulating layer and the first spacer, an organic layer in contact with the first electrode, a second electrode arranged on the organic layer, a second spacer partially arranged on the second insulating layer overlapping with a surrounding area, and a support member arranged on the second spacer.

### CROSS-REFERENCE TO RELATED APPLICATIONS

This application is a Continuation application of PCT Application No. PCT/JP2021/048241, filed Dec. 24, 2021 and based upon and claiming the benefit of priority from Japanese Patent Application No. 2021-030481, filed Feb. 26, 2021, the entire contents of all of which are incorporated herein by reference.

### FIELD

Embodiments described herein relate generally to a display device.

### BACKGROUND

Recently, a display device with an organic light-emitting diode (OLED) applied thereto as a display element has been put into practical use. The display element comprises an organic layer between a pixel electrode and a common electrode.

When a pixel arranged on a display area of such a display device is configured, for example, to comprise a plurality of sub-pixels displaying different colors, the organic layer described above is formed in each of the sub-pixels using, for example, a vapor deposition mask.

However, when the vapor deposition mask is used, a displacement and the like of the organic layer (in other words, the pixel) formed using the vapor deposition mask may occur, resulting in degradation in display quality in a display device.

### BRIEF DESCRIPTION OF THE DRAWINGS

FIG. 1 is a diagram showing a configuration example of a display device according to a first embodiment.

FIG. 2 is a diagram showing an example of a layout of sub-pixels included in pixels.

FIG. 3 is a diagram showing another example of the layout of the sub-pixels included in the pixels.

FIG. 4 is a diagram showing an example of a cross-section of a display area included in the display device.

FIG. 5 is a diagram showing an example of a spacer arranged on an insulating layer.

FIG. 6 is a diagram showing a cross-section of a boundary portion of a display area and a surrounding area in a comparative example of the present embodiment.

FIG. 7 is a diagram showing an example of a cross-section of a boundary portion of a display area and a surrounding area in the present embodiment.

FIG. 8 is a diagram for illustrating a position at which a support member is arranged.

FIG. 9 is a cross-sectional view taken along line B-B′ shown in FIG. 8.

FIG. 10 is a diagram for illustrating a second embodiment.

FIG. 11 is a plan view of a metal layer arranged on a surrounding area.

FIG. 12 is a diagram showing a shield member arranged at a position overlapping with a hole portion in the present embodiment.

FIG. 13 is a diagram showing an example of the shield member.

FIG. 14 is a diagram showing another example of the shield member.

### DETAILED DESCRIPTION

In general, according to one embodiment, a display device includes a base, a first insulating layer arranged on the base, a first electrode arranged on the first insulating layer overlapping with a pixel included in a display area, a second insulating layer arranged on the first insulating layer and including an aperture overlapping with the first electrode, a first spacer partially arranged on the second insulating layer overlapping with the display area, a partition arranged on the second insulating layer and the first spacer so as to separate the pixel, an organic layer in contact with the first electrode through the aperture, a second electrode arranged on the organic layer, a second spacer partially arranged on the second insulating layer overlapping with a surrounding area outside the display area, and a support member arranged on the second spacer and corresponding to the partition.

Embodiments will be described hereinafter with reference to the accompanying drawings.

The disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same elements as those described in connection with preceding drawings are denoted by like reference numerals, and a detailed description thereof is omitted unless otherwise necessary.

In the figures, an X-axis, a Y-axis and a Z-axis orthogonal to each other are described to facilitate understanding as needed. A direction along the X-axis is referred to as a first direction X, a direction along the Y-axis is referred to as a second direction Y, and a direction along the Z-axis is referred to as a third direction Z. In the present embodiment, viewing an X-Y plane defined by the direction X and the direction Y is referred to as a plan view. In addition, in the present embodiment, the third direction Z is defined as an upward direction, and a direction opposite to the third direction Z is defined as a downward direction. According to “a second member above/on a first member” and “a second member below/under a first member”, the second member may be in contact with the first member or may be remote from the first member.

The display device of the present embodiment is an organic electroluminescent display device comprising an organic light emitting diode (OLED) as a display element, and can be mounted on televisions, personal computers, mobile terminals, mobile phones and the like.

### First Embodiment

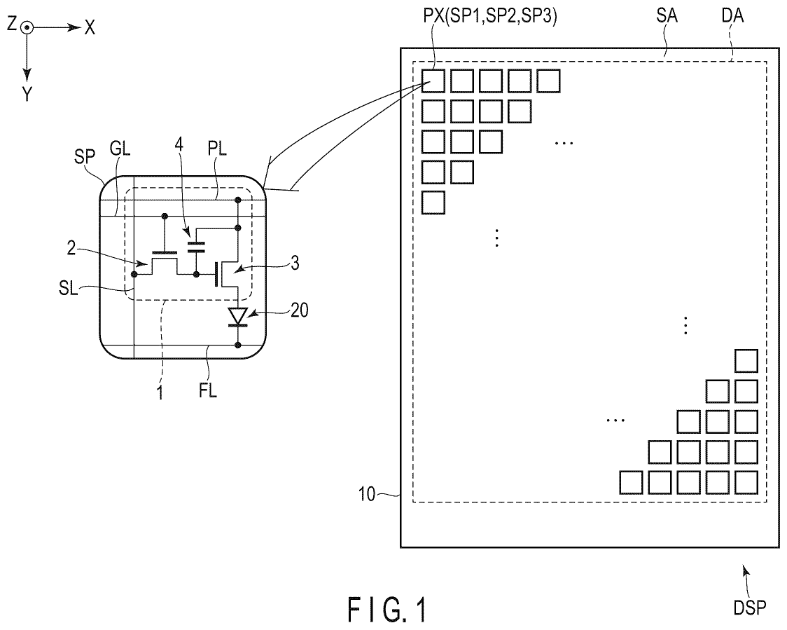

FIG. 1 is a diagram showing a configuration example of a display device DSP according to a first embodiment. The display device DSP includes a display area DA on which images are displayed and a surrounding area SA outside the display area DA, on an insulating base 10. The base 10 may be glass or a resin film having flexibility.

The display area DA includes a plurality of pixels PX arrayed in a matrix in the first direction X and the second direction Y. Each of the pixels PX comprises, for example, a plurality of sub-pixels SP. For example, the pixel PX comprises a sub-pixel SP1 for displaying red, a sub-pixel SP2 for displaying green, and a sub-pixel SP3 for displaying blue. In addition to the sub-pixels of the above three colors, the pixel PX may comprise four or more sub-pixels including a sub-pixel for displaying the other color such as white.

A configuration example of one sub-pixel SP included in the pixel PX will be described in brief. The sub-pixel SP comprises a pixel circuit 1 and a display element 20. The pixel circuit 1 comprises a pixel switch 2, a drive transistor 3, and a capacitor 4. The pixel switch 2 and the drive transistor 3 are switch elements, for example, constituted by thin-film transistors (TFT).

In the pixel switch 2, a gate electrode is connected to a scanning line GL, a source electrode is connected to a signal line SL, and a drain electrode is connected to one electrode constituting the capacitor 4 and the gate electrode of the drive transistor 3. In the drive transistor 3, the source electrode is connected to the other electrode constituting the capacitor 4 and a power line PL, and the drain electrode is connected to an anode electrode of the display element 20. A cathode electrode in the display element 20 is connected to a feeding line FL. The configuration of the pixel circuit 1 is not limited to the example shown in the figure.

The display element 20 is an organic light emitting diode (OLED) which is a light emitting element. In a case where the sub-pixel SP1 displays red as described above, the display element 20 included in the sub-pixel SP1 is configured to emit light corresponding to a red wavelength. In a case where the sub-pixel SP2 displays green as described above, the display element 20 included in the sub-pixel SP2 is configured to emit light corresponding to a green wavelength. In a case where the sub-pixel SP3 displays blue as described above, the display element 20 included in the sub-pixel SP3 is configured to emit light corresponding to a blue wavelength. The configuration of the display element 20 will be described later.

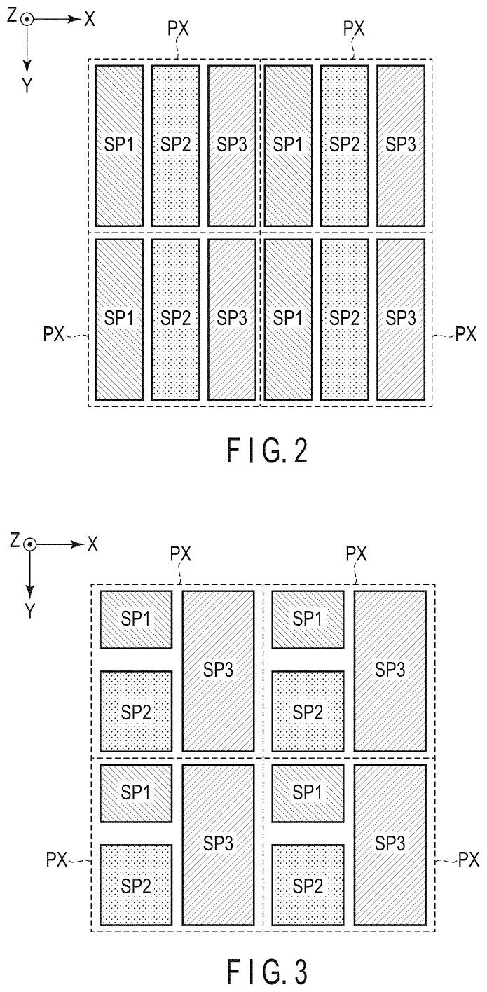

FIG. 2 shows an example of a layout of the plurality of sub-pixels SP (SP1, SP2, and SP3) included in the pixel PX. An explanation focusing on four pixels PX will be given.

The sub-pixels SP1, SP2, and SP3 which constitute one pixel PX are formed in an approximately rectangular shape extending in the second direction Y and arranged in the first direction X. When two pixels PX arranged in the first direction X are focused, colors displayed on the adjacent sub-pixels SP are different from each other. In addition, when two pixels PX arranged in the second direction Y are focused, colors displayed on the adjacent sub-pixels SP are the same. An area of each of the sub-pixels SP1, SP2, and SP3 may be the same or different from each other.

FIG. 3 shows another example of the layout of the plurality of sub-pixels SP (SP1, SP2, and SP3) included in the pixel PX.

The sub-pixels SP1 and SP2, which constitute one pixel PX are arranged in the second direction Y, the sub-pixels SP1 and SP3 are arranged in the first direction X, and the sub-pixels SP2 and SP3 are arranged in the first direction X. The sub-pixel SP1 is formed in the approximately rectangular shape extending in the first direction X, and the sub-pixels SP2 and SP3 are formed in the approximately rectangular shape extending in the second direction Y. The area of the sub-pixel SP2 is larger than that of the sub-pixel SP1, and the area of the sub-pixel SP3 is larger than that of the sub-pixel SP2. The area of the sub-pixel SP1 may be the same as that of the sub-pixel SP2.

When two pixels PX arranged in the first direction X are focused, colors displayed on the sub-pixels SP adjacent to each other in the first direction X are different from each other in an area in which the sub-pixels SP1 and SP3 are alternately arranged and in an area in which the sub-pixels SP2 and SP3 are alternately arranged. On the other hand, when the two pixels PX arranged in the second direction Y are focused, light emission colors of the sub-pixels SP adjacent to each other in the second direction Y are different from each other in an area in which the sub-pixels SP1 and SP2 are alternately arranged. In addition, the colors displayed on the sub-pixels SP adjacent to each other in the second direction Y are the same in an area in which the plurality of sub-pixels SP3 are arranged.

An outer shape of each of the sub-pixels SP (SP1, SP2, and SP3) shown in FIGS. 2 and 3 corresponds to an outer shape of an area where a color is displayed on each of the sub-pixels SP (in other words, a light emitting area), but is shown in a simplified form and does not necessarily reflect an actual shape.

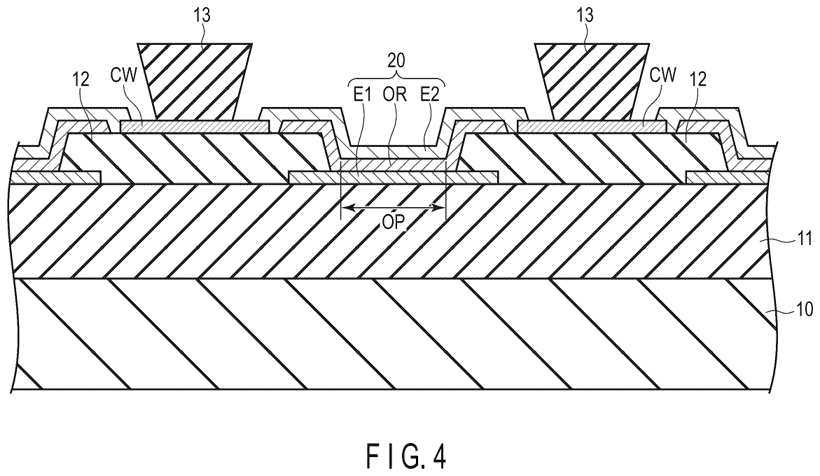

Next, the display device DSP according to the present embodiment will be described with reference to FIG. 4. FIG. 4 shows an example of a cross-section of the display area DA included in the display device DSP. A configuration of the display element 20 which one sub-pixel SP included in the pixel PX comprises will be mainly explained.

The insulating layer 11 is arranged on the base 10. The pixel circuit 1 shown in FIG. 1 is arranged on the base 10 and is covered with the insulating layer 11, but omitted in FIG. 4. The insulating layer 11 corresponds to an under layer of the display element 20 and is an organic insulating layer, for example, formed of an organic material.

An insulating layer 12 is arranged on the insulating layer 11. The insulating layer 12 is the organic insulating layer, for example, formed of the organic material. The insulating layer 12 is formed so as to partition the display element 20 or the pixel PX comprising this display element 20 and may be referred to as, for example, a rib and the like.

The display element 20 comprises a first electrode E1, an organic layer OR, and a second electrode E2. The first electrode E1 is the electrode arranged for each display element 20 or each sub-pixel SP, and may be referred to as a pixel electrode, a lower electrode, an anode electrode, or the like. The second electrode E2 is the electrode arranged for the plurality of display elements 20 or the plurality of pixels PX (sub-pixels SP) in common, and may be referred to as a common electrode, a counter-electrode, an upper electrode, a cathode electrode, or the like. The emitting layer (included in the organic layer OR) can emit light by forming a potential difference between the first electrode E1 and the second electrode E2 (in other words, by supplying a driving current). The first electrode E1 is arranged on the insulating layer 11, and a peripheral portion thereof is covered with the insulating layer 12. The first electrode E1 is electrically connected to the drive transistor 3 shown in FIG. 1. The first electrode E1 is a transparent electrode formed of, for example, a transparent conductive material such as indium tin oxide (ITO) or indium zinc oxide (IZO). The first electrode E1 may be a metal electrode formed of a metallic material such as silver or aluminum. In addition, the first electrode E1 may be a stacked layer body of the transparent electrode and the metal electrode. Further, the first electrode E1 may be constituted as the stacked layer body formed by stacking the transparent electrode, the metal electrode, and the transparent electrode in this order, or may be constituted as the stacked layer body of three or more layers.

The insulating layer 12 includes an aperture OP overlapping with the first electrode E1 in each of the sub-pixels SP. In this case, the organic layer OR is arranged on the insulating layer 12 and in contact with the first electrode E1 through the aperture OP.

The second electrode E2 is arranged on the organic layer OR so as to cover the organic layer OR. The second electrode E2 is the transparent electrode formed of, for example, the transparent conductive material such as ITO or IZO. The second electrode E2 may be covered with a transparent protective film (comprising at least one of an inorganic insulating film and an organic insulating film).

In the display device DSP, a partition 13 is arranged at a position corresponding to the boundary between the sub-pixels SP. The partition 13 has an inverse tapered shape. The inverse tapered shape means a shape in which a width of an upper portion is larger than that of a lower portion (bottom portion), similarly to the partition 13 shown in FIG. 4. A side surface of the partition 13 may be a flat surface inclined to the third direction Z or a curved surface. In addition, the partition 13 may be constituted by a plurality of portions whose width gradually becomes smaller from the upper portion to the lower portion.

The partition 13 is formed so as to overlap with the insulating layer 12 in a plan view and partition each of the sub-pixels SP. According to the partition 13, since the organic layer OR in contact with the first electrode through the aperture OP of the insulating layer 12 can be formed so as to be divided for each of the sub-pixels, a horizontal leakage occurring from, for example, an end of the organic layer OR of one of the adjacent sub-pixels SP overlapping with an end of the organic layer OR of the other sub-pixel SP can be suppressed.

In addition, the second electrode E2 is formed so as to cover the organic layer OR. According to the configuration comprising the partition 13 formed to partition the pixels PX as described above, the organic layer OR and the second electrode E2 are formed in an area surrounded by the partition 13 in the plan view (in other words, an area overlapping with the sub-pixel SP) by partitioning.

By the way, the second electrode E2 is the electrode arranged in common to the plurality of above display elements 20 or the plurality of pixels PX, and a common voltage is applied to the second electrode E2. However, as described above, the second electrode E2 is formed to be partitioned for each of the sub-pixels SP. For this reason, in the display device DSP, for example, the second electrode E2 formed on a position overlapping with the sub-pixels SP and the second electrode E2 formed on a position overlapping with the sub-pixel SP adjacent to this sub-pixel SP are connected to each other via an auxiliary wire (cathode wire) CW. The auxiliary wire CW is formed of the metallic material and arranged on the insulating layer 12. In this case, the above partition 13 is arranged on the auxiliary wire CW. The plurality of second electrodes E2 connected to each other via the auxiliary wire CW in this manner are electrically connected to, for example, the feed line FL arranged in the surrounding area SA.

In a case where the sub-pixel SP1 displays red, as described above, the organic layer OR emitting red light needs to be formed in the display element 20 in the sub-pixel SP1 (in other words, a position overlapping with the sub-pixel SP1). In addition, when the sub-pixel SP2 displays green, the organic layer OR emitting green light needs to be formed in the display element 20 in the sub-pixel SP2 (in other words, a position overlapping with the sub-pixel SP2). In addition, when the sub-pixel SP3 displays blue, the organic layer OR emitting blue light needs to be formed in the display element 20 in the sub-pixel SP3 (in other words, a position overlapping with the sub-pixel SP3).

In this case, the above organic layer OR is formed by, for example, vacuum deposition, but since the organic layers OR emitting different colors cannot be formed simultaneously, the organic layer OR is formed per, for example, color emitted by using the vapor deposition mask (in other words, sub-pixels SP displaying different colors).

In a case where the organic layer OR is formed by using the vapor deposition mask, when a distance between the sub-pixel SP (the first electrode E1) and the vapor deposition mask is short, the vapor deposition mask is brought into contact with the sub-pixel SP and the sub-pixel SP may be damaged by a foreign matter and the like.

For this reason, it is assumed that a spacer is partially arranged on, for example, the insulating layer 12 overlapping with the display area DA.

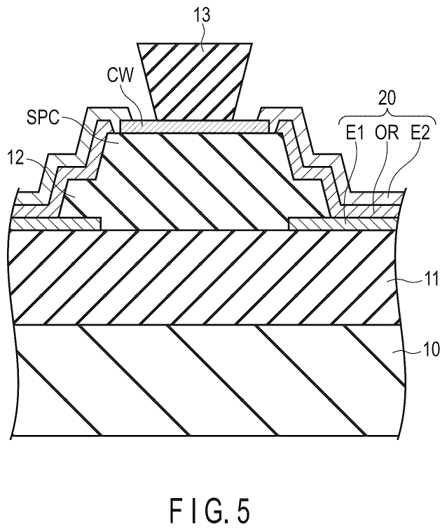

FIG. 5 shows an example of the spacer arranged on the insulating layer 12. In FIG. 5, it is assumed that the spacer SPC is formed of the same material (organic material) as the insulating layer 12 (in other words, integrally formed as the insulating layer 12). However, the spacer SPC may be formed as a portion different from the insulating layer 12.

In a case where the spacer SPC is arranged on the insulating layer 12 as shown in FIG. 5, the auxiliary wire CW is arranged between the spacer SPC and the partition 13.

The spacer SPC is partially arranged on the insulating layer 12 as described above. When the interval at which the spacers SPC are arranged is excessively wide, the vapor deposition mask for forming the organic layer OR cannot be properly supported, and when the interval at which the spacers SPC are arranged is excessively narrow, the foreign matter easily adheres to the partition 13 which is mounted on the spacer SPC while using the vapor deposition mask. Therefore, the spacers SPC are preferably arranged at a moderate interval. More specifically, in a case where the plurality of sub-pixels SP are arranged in the layout shown in the above FIG. 3, the spacer SPC can be arranged between the sub-pixel SP1 and the sub-pixel SP2 in a plan view.

In a case where the spacer SPC is arranged on the insulating layer 12 as described above, the partition 13 is arranged on the spacer SPC (and the auxiliary wire CW). When the organic layer OR is formed by using the vapor deposition mask in such a configuration, since the vapor deposition mask is arranged on the partition 13, a proper distance between each of the sub-pixels SP and the vapor deposition mask can be maintained by the spacer SPC and the partition 13, and the sub-pixels SP being damaged by the foreign matter and the like can be suppressed.

In a case where the spacer SPC is formed in the display area DA, the spacer SPC is formed in the surrounding area SA outside the display area DA as well in order to simplify the process for forming the spacer SPC.

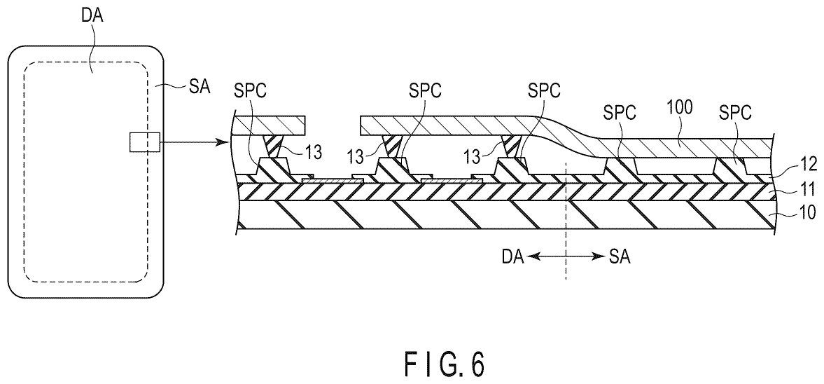

The display device according to a comparative example of the present embodiment will now be described with reference to FIG. 6. FIG. 6 schematically shows an example of a cross-section of a boundary portion of a display area DA and a surrounding area SA included in a display device of a comparative example of the present embodiment. FIG. 6 shows a state when an organic layer OR is formed using a vapor deposition mask 100 and omits a second electrode E2 which is formed after the organic layer OR and the like.

As described above, the partition 13 for separating the sub-pixels SP is arranged in the display area DA comprising the pixel PX (sub-pixels SP). However, in the comparative example of the present embodiment, the partition 13 is not arranged in the surrounding area SA which does comprise the pixel PX (sub-pixels SP).

In such a configuration, since the spacers SPC are formed over the display area DA and the surrounding area SA as described above and the partition 13 is not arranged in the surrounding area SA, the display area DA and the surrounding area SA are different in positions (heights) for supporting the vapor deposition mask 100 used for forming the organic layer OR. More specifically, in the surrounding area SA, the position for supporting the vapor deposition mask 100 is lower by not arranging the partition 13. In this case, when the organic layer OR is formed by using the vapor deposition mask 100, a distortion occurs in the vapor deposition mask 100 and can be a factor of the displacement of the organic layer OR (in other words, the sub-pixel SP) formed using the vapor deposition mask. In addition, since the distance between the vapor deposition mask 100 and the insulating layer 12 is short in the surrounding area SA, the foreign matter adhered to the vapor deposition mask 100 is transferred to the insulating layer 12 side and can be a factor of, for example, a dark spot (non-illuminating pixels). In other words, according to the comparative example of the present embodiment, the degradation in display quality may be caused by the displacement of the organic layer OR, the dark spot and the like.

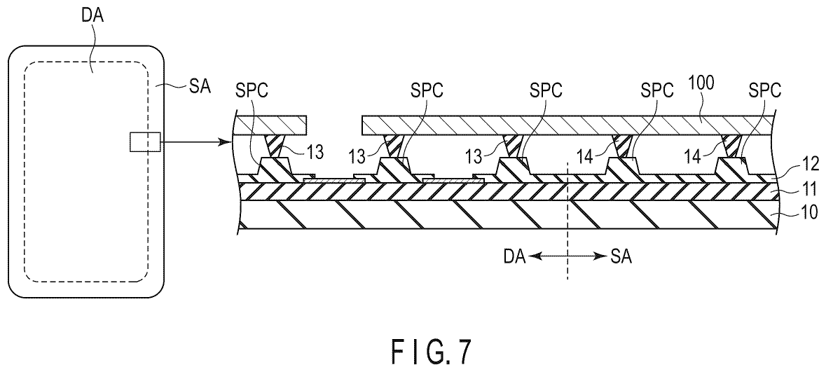

For this reason, in the present embodiment, as shown in FIG. 7, a support member 14 corresponding to the above partition 13 is further arranged on the spacer SPC arranged on the insulating layer 12 overlapping with the surrounding area SA.

In this case, the support member 14 is formed such that the height (thickness of the third direction Z) of the spacer SPC and the support member 14 arranged in the surrounding area SA to be substantially the same as the height (thickness of the third direction Z) of the spacer SPC and the partition 13 arranged in the display area DA. Since the partition 13 is arranged on the auxiliary wire CW in the display area DA, the support member 14 may be formed such that the height of the spacer SPC and the support member 14 arranged in the surrounding area SA are the same as the height of the spacer SPC, the partition 13, and the auxiliary wire CW arranged in the display area DA.

In addition, although it is assumed in the present embodiment that the support member 14 is formed of, for example, the same material as the partition 13, and has the same shape as the partition 13 (inverse tapered shape), but the support member 14 may be formed of a material different from that of the partition 13, and have the shape different from that of the partition 13.

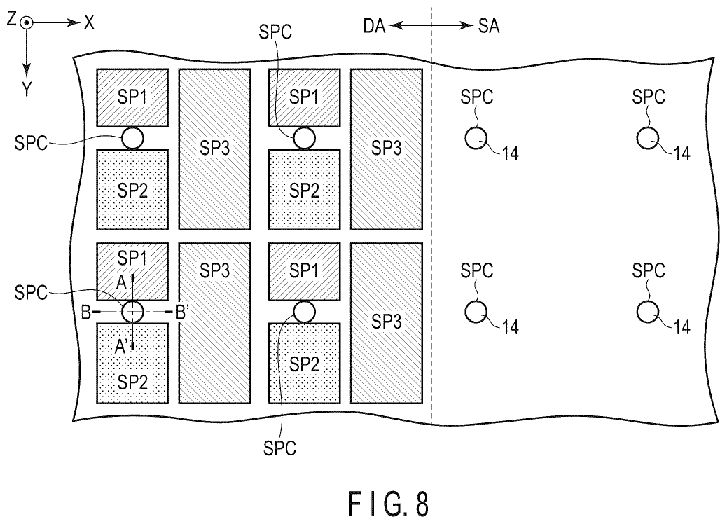

Next, an example of a position at which the support member 14 is arranged in the present embodiment will be explained with reference to FIG. 8. Here, a case in which each of the sub-pixels SP is arranged in the display area DA in the above-described layout shown in FIG. 3 is assumed.

First, the spacer SPC arranged on the insulating layer 12 overlapping with the display area DA (for convenience, hereinafter referred to as a first spacer) will be explained.

As shown in FIG. 8, it is assumed that the first spacer SPC is arranged, for example, between the sub-pixels SP1 and SP2 constituting the pixel PX in the plan view. In other words, the first spacers SPC are arranged on the insulating layer 12 at regular intervals in the display area DA.

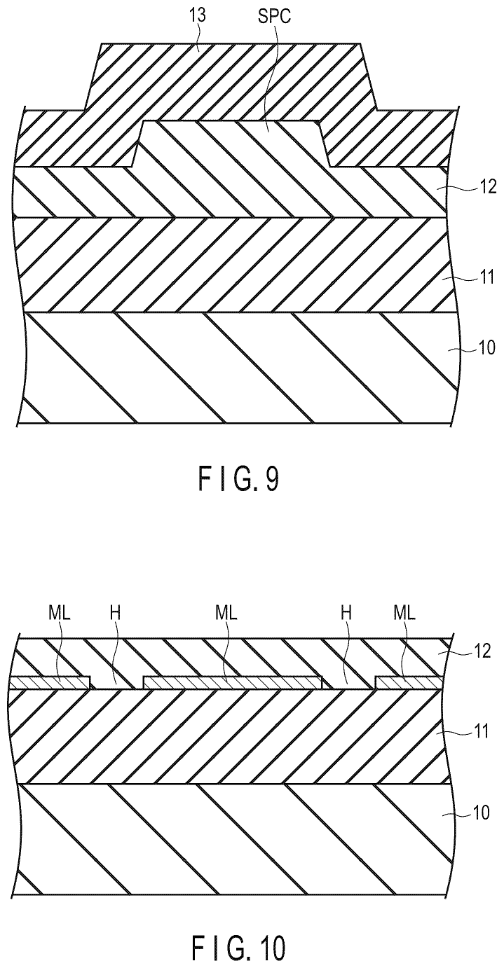

As described above, each of the sub-pixels SP shown in FIG. 8 is partitioned by the partition 13, and the above FIG. 5 shows a cross-section along A-A′ line shown in FIG. 8. On the other hand, FIG. 9 shows a cross-section along B-B′ line shown in FIG. 8.

Since the support member 14 is arranged on the spacer SPC (for convenience, hereinafter referred to as a second spacer) arranged in the surrounding area SA as described above, it is assumed that the plurality of spacers SPC are formed at the same intervals as the plurality of first spacers SPC arranged in the display area DA.

In other words, in the present embodiment, when the first spacers SPC are arranged in the display area DA at the regular intervals as described above, the second spacers SPC are similarly arranged in the surrounding area SA at regular intervals. In addition, the intervals at which the second spacers SPC are partially arranged on the insulating layer 12 are approximately the same as the intervals at which the first spacers SPC are partially arranged on the insulating layer 12.

Although the case in which the first spacer SPC is arranged between the sub-pixels SP1 and SP2, and the second spacers SPC are arranged at approximately the same intervals as those of the first spacers SPC is explained in FIG. 8, the position and the interval at which the first and second spacers SPC are arranged may be different from those shown in FIG. 8. More specifically, the position and the interval at which the first and second spacers SPC are arranged may be determined according to, for example, the layout and the like of the pixel PX (sub-pixels SP), or according to the material and the like of the vapor deposition mask used to form the organic layer OR.

As described above, in the present embodiment, the support member 14 corresponding to the partitions 13 is further arranged on the second spacer SPC in the display device DSP comprising the first spacer SPC partially arranged on the insulating layer 12 (second insulating layer) overlapping with the display area DA, the partition 13 arranged on the first spacer SPC, and the second spacer SPC partially arranged on the insulating layer 12 overlapping with the surrounding area SA. According to such a configuration, since the vapor deposition mask 100 is arranged in the display area DA and the surrounding area SA in a flat state when being used (in other words, in the vapor deposition of the organic layer OR), contact between the vapor deposition mask 100 with the sub-pixel SP, the surrounding area SA (insulating layer 12), and the like can be suppressed. According to this, a damage to the sub-pixel SP and the surrounding area SA (generation of the dark spots) and the displacement of the organic layer OR (sub-pixel SP) in the vapor deposition can be prevented, and an occurrence of the degradation in display quality in the display device DSP can be suppressed.

In order to arrange the vapor deposition mask 100 in the flat state as described above, the height (length in the third direction Z) of the second spacer SPC and the support member 14 should preferably be substantially the same as the height (length in the third direction Z) of the first spacer SPC and the partition.

In addition, in the present embodiment, the first spacers SPC are arranged on the insulating layer 12 overlapping with the display area DA at the regular intervals, and the second spacers SPC are arranged on the insulating layer 12 overlapping with the surrounding area SA at regular intervals. Further, in the present embodiment, the intervals at which the second spacers SPC are partially arranged on the insulating layer 12 are substantially the same as the intervals at which the first spacers SPC are partially arranged on the insulating layer 12. In the present embodiment, according to such a configuration, the vapor deposition mask 100 can be stably provided when the organic layer OR is formed.

In addition, in the present embodiment, a process for forming the first and second spacers SPC can be simplified by, for example, forming the first and second spacers SPC of the same material as the insulating layer 12. The first and second spacers SPC may be formed of a material different from that of the insulating layer 12 (in other words, by a process different from the process for forming the insulating layer 12).

In addition, in the present embodiment, the partition 13 is formed to have a shape in which the width of the upper portion is larger than that of the lower portion (for example, the inverse tapered shape). According to such a partition 13, it is possible to appropriately separate the organic layer OR for each pixel and suppress an occurrence of a lateral leakage described above, for example, even when a minor displacement occurs in a position where the organic layer OR is vapor deposited.

In the present embodiment, for example, the second electrode E2 arranged at a position overlapping with the sub-pixel SP (first pixel) is connected to the second electrode E2 arranged at the position overlapping with the sub-pixel SP adjacent to the sub-pixel SP (first pixel) via the auxiliary wire arranged between the insulating layer 12 or the first spacer SPC and the partition 13. According to this, a common voltage can be applied to each of the sub-pixels SP through the second electrode E2 even in a configuration in which the partition 13 partitioning the sub-pixels SP is arranged.

In the present embodiment, the case in which the support member 14 is arranged on only the second spacer SPC has been described, but the support member 14 needs only to be arranged on at least the second spacer SPC. In other words, in a case where the support member 14 is simultaneously formed in a process for forming the partition 13, the support member 14 may be formed on not only the second spacer SPC (in other words, a position overlapping with the second spacer SPC) but also other areas in the surrounding area SA.

### Second Embodiment

Next, a second embodiment will be described. In the following explanation, detailed descriptions of the same portions as those of the above first embodiment will be omitted. The portions different from those of the first embodiment will mainly be described.

First, the present embodiment will be explained with reference to FIG. 10. FIG. 10 shows an example of a cross-section of a surrounding area SA included in a display device of the present embodiment. In the display area DA in the display device DSP of the first embodiment described above, the first electrode E1 is arranged on the insulating layer 11. On the other hand, in the surrounding area SA in the display device of the present embodiment, as shown in FIG. 10, a metal layer ML formed of silver, aluminum, or the like is arranged on the insulating layer 11 (in other words, on the same layer as the first electrode E1). In FIG. 10, a configuration arranged above the insulating layer 12 is omitted.

This metal layer ML is used, for example, as a wire (cathode wire) to connect the above second electrode E2 to a feed line FL or the like arranged in the surrounding area SA.

The insulating layer 11 on which the metal layer ML is arranged is formed of an organic material, thereby, moisture or gas is generated from the organic material forming the insulating layer 11 when the metal layer ML is formed. Therefore, when the metal layer ML is formed on a wide range of the surrounding area SA, the metal layer ML may be peeled off from the insulating layer 11.

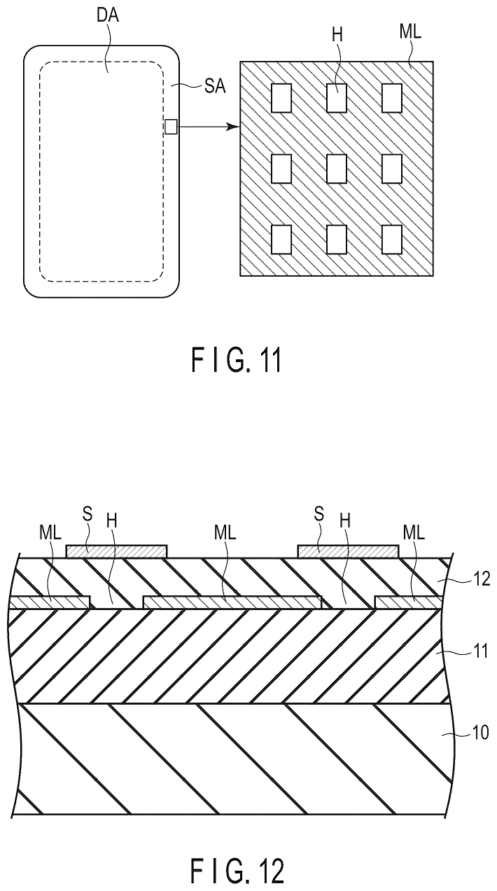

For this reason, a plurality of hole portions H are formed in the metal layer ML arranged in the surrounding area SA. FIG. 11 is a plan view showing the metal layer ML arranged in the surrounding area SA as described above. In an example shown in FIG. 11, the plurality of hole portions H formed in a rectangular shape are formed at predetermined intervals, but the plurality of hole portions H may be formed in a shape (pattern) or at an interval, and the like different from those shown in FIG. 11. In addition, the metal layer ML may also be formed in a shape different from that in FIG. 11.

The insulating layer 11 is exposed by the plurality of hole portions H, and thus moisture and gas desorbed from the organic material forming the insulating layer 11 can be removed.

In the surrounding area SA in the display device DSP, a circuit unit (for example, a gate drive circuit connected to the scanning line GL described above, and the like) comprising TFT is provided on a lower layer of the metal layer ML, and the above metal layer ML has a function of a light-shielding layer capable of preventing entry of light to the gate drive circuit as well.

When the plurality of holes H are formed in the metal layer ML as described above, a light leakage may occur in the transistor of the circuit unit due to entry of strong light to the circuit unit through the plurality of hole portions H.

For this reason, in the display device DSP of the present embodiment, a shield member (light-shielding member) S is further arranged on the insulating layer 12 overlapping with the hole portions H formed in the metal layer ML arranged in the surrounding area SA, as shown in FIG. 12. The shield member S is formed of, for example, the metallic material and the like.

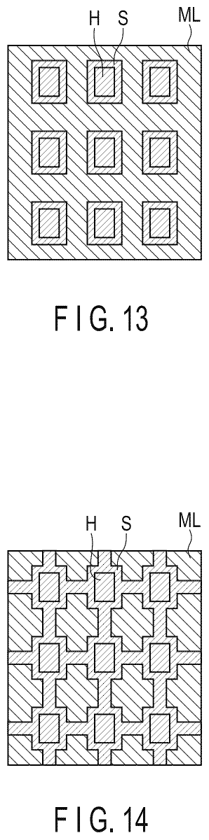

An example of a shape of the shield member S is explained with reference to FIG. 13. FIG. 13 shows a plan view of the metal layer ML and the shield member S. In FIG. 13, the shield member S is formed in an island-like shape at a position overlapping with each of the plurality of hole portions H formed in the metal layer ML so as to block the hole portions H. According to this, the above light leakage can be suppressed since the shield member S blocks light that enters the circuit unit through the plurality of hole portions H. In other words, in the present embodiment, a malfunction of the circuit unit (gate drive circuit and the like) due to the light leakage does not occur, and the degradation in display quality in the display device DSP can be avoided.

In addition, as shown in FIG. 14, it is also possible to adopt a configuration in which the shield members S formed in a position overlapping with each of the plurality of hole portions H are connected to each other. According to this configuration, the shield member S can be used as the cathode wire and the like while suppressing the above light leakage.

It is assumed that the configuration explained in the present embodiment is realized to be combined with the configuration explained in the first embodiment described above, but may be realized as a configuration independent of the configuration explained in the first embodiment.

All display devices, which are implementable with arbitrary changes in design by a person of ordinary skill in the art based on the display devices described above as the embodiments of the present invention, belong to the scope of the present invention as long as they encompass the spirit of the present invention.

Various modifications are easily conceivable within the category of the idea of the present invention by a person of ordinary skill in the art, and these modifications are also considered to belong to the scope of the present invention. For example, additions, deletions or changes in design of the constituent elements or additions, omissions or changes in condition of the processes may be arbitrarily made to the above embodiments by a person of ordinary skill in the art, and these modifications also fall within the scope of the present invention as long as they encompass the spirit of the present invention.

In addition, the other advantages of the aspects described in the above embodiments, which are obvious from the descriptions of the specification or which are arbitrarily conceivable by a person of ordinary skill in the art, are considered to be achievable by the present invention as a matter of course.

What is claimed is:

1. A display device comprising:
a base;
a first insulating layer arranged on the base;
a first electrode arranged on the first insulating layer overlapping with a pixel included in a display area;
a second insulating layer arranged on the first insulating layer and including an aperture overlapping with the first electrode;
a first spacer partially arranged on the second insulating layer overlapping with the display area;
a partition arranged on the second insulating layer and the first spacer so as to separate the pixel;
an organic layer in contact with the first electrode through the aperture;
a second electrode arranged on the organic layer;
a second spacer partially arranged on the second insulating layer overlapping with a surrounding area outside the display area; and
a support member arranged on the second spacer and corresponding to the partition.

2. The display device of claim 1, wherein
a height of the second spacer and the support member is substantially the same as a height of the first spacer and the partition.

3. The display device of claim 1, wherein
the first spacers are arranged at regular intervals on the second insulating layer overlapping with the display area, and
the second spacers are arranged at regular intervals on the second insulating layer overlapping with the surrounding area.

4. The display device of claim 3, wherein
the intervals at which the second spacers are arranged on the second insulating layer are substantially the same to the intervals at which the first spacers are arranged on the second insulating layer.

5. The display device of claim 1, wherein
the first spacer and the second spacer are formed of the same material as the second insulating layer.

6. The display device of claim 1, wherein
the partition has a shape in which a width of an upper portion is larger than a width of a lower portion.

7. The display device of claim 1, wherein
the second electrode overlapping with a first pixel is connected to the second electrode overlapping with a second pixel adjacent to the first pixel via an auxiliary wire arranged on between the second insulating layer or the first spacer and the partition.
